(19) United States
(12) Patent Application Publication
(10) Pub. No.: US 2024/0224543 A1
(43) Pub. Date: Jul. 4, 2024

(54) STACKED MULTICHIP IC DEVICE PACKAGES INCLUDING A GLASS SUBSTRATE

(71) Applicant: Intel Corporation, Sant Clara, CA (US)

(72) Inventors: Suddhasattwa Nad, Chandler, AZ (US); Gang Duan, Chandler, AZ (US); Srinivas Pietambaram, Chandler, AZ (US); Brandon Marin, Gilbert, AZ (US); Jeremy Ecton, Gilbert, AZ (US)

(73) Assignee: Intel Corporation, Santa Clara, CA (US)

(21) Appl. No.: 18/091,264

(22) Filed: Dec. 29, 2022

(51) Int. Cl. H10B 80/00; H01L 21/48; H01L 23/15; H01L 23/498

(52) U.S. Cl. CPC H10B 80/00; H01L 21/486; H01L 23/15; H01L 23/49827

(57) ABSTRACT

Multi-chip/die device including a logic IC die facing a first side of a glass substrate and a memory IC die facing, and coupled to, the logic IC die. First ones of first metallization features of the logic IC die are coupled to through-glass vias extending through a thickness of the glass substrate. The memory IC die is coupled to second ones of the first metallization features, either directly or by way of other through-glass vias. The logic IC die and/or memory IC die may be directly bonded to the through-glass vias or may be attached by solder. The logic IC die or memory IC die may be embedded within the glass substrate. Through-glass vias within a region beyond an edge of the memory IC die may couple the logic IC die to a host component either through a routing structure built up adjacent the memory IC die, or through solder features attached to the glass substrate adjacent to the memory IC die.

### BACKGROUND

Monolithic integrated circuit (IC) fabrication has restrictions that may limit a final device's performance, and thus different versions of IC die disaggregation are being investigated. To date however, these techniques and architectures generally suffer from certain drawbacks such as high cost, lower insertion efficiency, and increased z-height.

In electronics manufacturing, IC packaging is a stage of semiconductor device fabrication in which an IC that has been monolithically fabricated on a chip (or die) comprising a semiconducting material is assembled into a “package” that can protect the IC chip from physical damage and support electrical contacts that connect the IC to a scaled host component, such as an organic package substrate, or a printed circuit board. Multiple chips can be similarly assembled, for example, into a multi-chip package (MCP).

The electrical interconnection between multiple IC dies is important to ensure device performance is sufficient as die-to-die communication demands can be significantly higher than die-to-host demands. Die-to-die interconnection may be achieved with an embedded die that hosts the interconnect routing. One motivation behind such as solution is that organic dielectric material employed within most packages suffers from high total thickness variation (TTV) and, thus, a large depth of focus (DOF) requirement can limit the resolution of lithography employed to define package metallization features that interconnect two IC die(s).

However, embedding an interconnect bridge die inside a package substrate cavity is challenging. Another difficulty is that die-to-die communication relies heavily on the die bump pitch, which is ultimately limited by the relative bump thickness variation (rBTV) of solder bumps. Current approaches to reduce BTV include the planarization (e.g., CMP) of dielectric build-up material, advanced lamination technologies, bump planarization, and bump plating uniformity improvements. However, these approaches are all expected to significantly reduce factory capacity and increase capital expenditure.

Accordingly, alternative die packaging architectures that can improve electrical performance and reduce bump pitch, enabling more die-to-die connections may be commercially advantageous.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 illustrates a flow diagram of methods for forming a multi-chip device structure including a glass substrate with through vias coupled to a first IC die and a second IC die stacked with the first IC die, in accordance with some embodiments;

FIG. 2 illustrates cross-sectional view of one or more workpieces comprising a glass substrate with conductive through vias, in accordance with some embodiments;

FIG. 3A illustrates a cross-sectional view of one or more workpieces, in accordance with some further embodiments;

FIG. 3B illustrates a plan view of the one or more workpieces illustrated in FIG. 3A, in accordance with some embodiments;

FIG. 4A illustrates a cross-sectional view of a first IC die coupled to through vias, in accordance with some embodiments;

FIG. 4B illustrates a plan view of the one or more workpieces illustrated in FIG. 4A, in accordance with some embodiments;

FIG. 5A illustrates a cross-sectional view of a second IC die coupled to the first IC die, in accordance with some embodiments;

FIG. 5B illustrates a plan view of the one or more workpieces illustrated in FIG. 5A, in accordance with some embodiments;

FIG. 6 illustrates a cross-sectional view of one or more workpieces with a package dielectric and metallization features adjacent to an edge of an IC die, in accordance with some embodiments;

FIG. 7 illustrates a cross-sectional view of one or more workpieces with first level interconnect (FLI) features adjacent to an edge of an IC die, in accordance with some embodiments;

FIGS. 8A, 8B and 8C illustrate systems including a multi-chip device assembled to a host component with FLI features, in accordance with some embodiments;

FIG. 9 illustrates a mobile computing platform and a data server machine employing a multi-chip package, in accordance with some embodiments; and

FIG. 10 is a functional block diagram of an electronic computing device, in accordance with some embodiments.

### DETAILED DESCRIPTION OF EXEMPLARY EMBODIMENTS

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

Multi-chip device structures including a first IC die, for example comprising logic circuitry, attached to a glass substrate and electrically coupled to electrically conductive through-glass vias (TGVs) extending through the glass substrate. The multi-chip device structures further include a second IC die, for example comprising memory circuitry, positioned in a stack with the first IC die. The second IC die is electrically coupled to the first IC die either through some of the TGVs or directly through die-to-die interconnects. Accordingly, a third IC (bridge) die is not needed for interconnection of the first and second IC dies. Each of the first and second IC dies may be solder bonded, or directly bonded to either the TGVs or to metallization features of the other IC die. High interconnect density, as well as direct bonding, is facilitated by flatness and/or thickness control of the glass substrate that is superior to organic cored/coreless substrates. Assembling the interconnect IC die into a stack with a glass substrate in accordance with embodiments herein may therefore enable low TTV and good dimensional stability for multi-chip devices.

Package dielectric and metallization features, for example comprising a redistribution layer (RDL) on a side of the glass substrate where TGVs are beyond an edge of one of the IC dies may terminate at first level interconnect (FLI) interfaces. Packaging dielectric(s) may be applied adjacent to, and over at least one of the IC die, for example to form a routing structure electrically coupled to the TGVs. Patterned metallization features may be embedded within the packaging dielectric(s) and terminated with package-to-host (e.g., first-level) interconnect interfaces. These multi-chip devices may be further assembled to a host component (e.g., through first-level interconnect solder features).

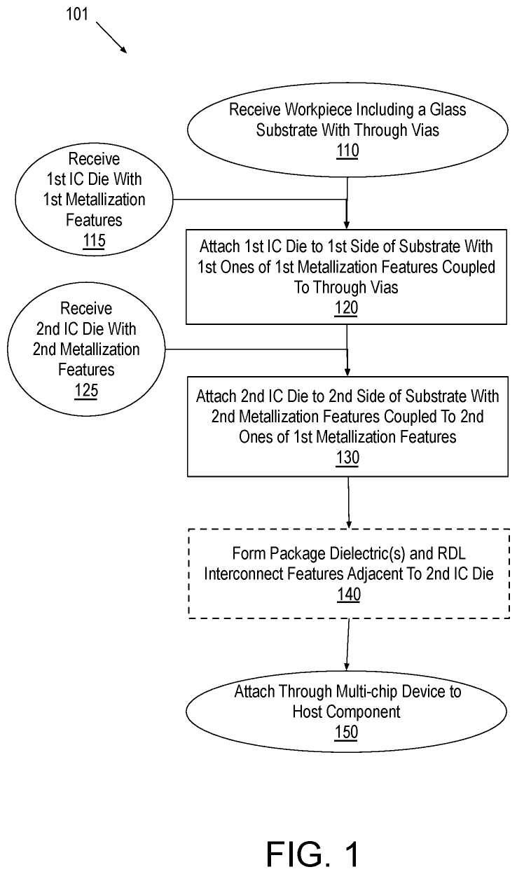

A variety of fabrication methods may be practiced to form multi-chip device structures having one or more of the features or attributes described herein. FIG. 1 illustrates a flow diagram of methods 101 for forming a multi-chip device structure including a first IC die coupled to through vias in a glass substrate and including a second IC die stacked with the first IC die, in accordance with some embodiments.

Methods 101 begin at input 110 with the receipt of a glass substrate that has been fabricated upstream of methods 101. The glass substrate ideally has a flatness comparable to that of a silicon wafer, and may either be the size of a typical silicon wafer (e.g., 300-400 mm) or have larger dimensions (e.g., suitable for large format panel processing), etc. In some examples, the glass substrate is of sufficient thickness to provide mechanical support to a workpiece as one or more multi-chip devices are fabricated and/or assembled upon the workpiece. Alternatively, the glass substrate may be supported by another handle substrate, such as any of those known to be suitable for a glass substrate of particular dimensions.

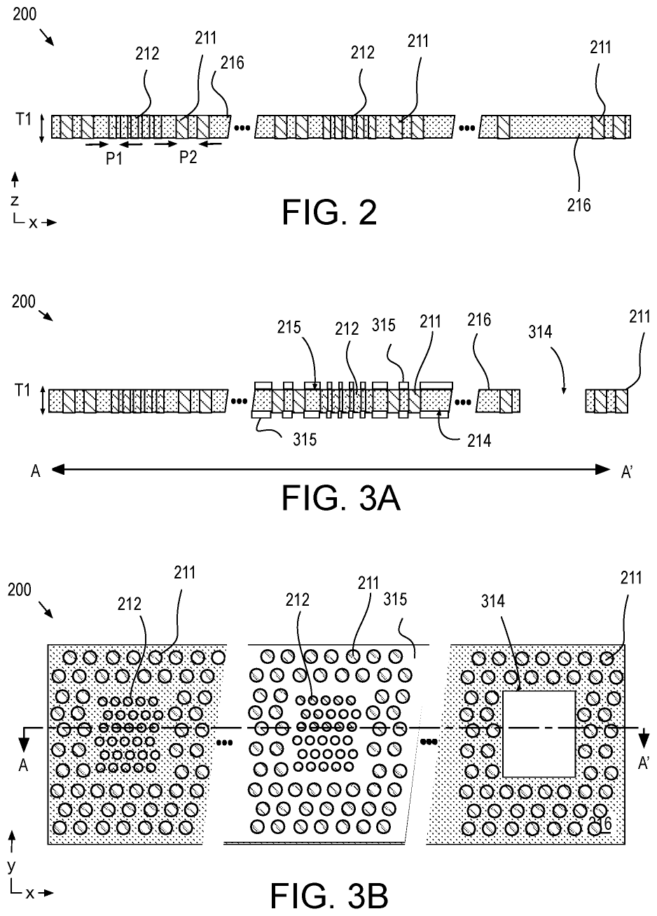

FIG. 2 illustrates cross-sectional view of one or more workpieces 200 comprising a glass substrate 216 with conductive through vias 211 and 212, in accordance with some embodiments. In some exemplary embodiments, glass substrate 216 is a single monolithic or contiguous bulk piece of glass. The composition of the glass may vary. However, in some examples glass substrate 216 is predominantly silica (e.g., silicon and oxygen) and may further include one or more metals, such as, but not limited to aluminum, beryllium, magnesium, calcium, strontium barium, or radium. Additional dopants (e.g., boron, phosphorus) may also be present in glass substrate 216 (e.g., borosilicate glass, etc.).

Any number of electrically conductive through-glass vias (TGVs) may extend through the entire thickness T1 of glass substrate 216. Thickness T1 may vary with implementation, but an exemplary thickness range is 20 μm to 200 μm. In accordance with some embodiments depicted in FIG. 2, TGVs 212 have a lateral pitch P1 within at least one dimension (e.g., along x-axis) that is sufficiently small to be interconnected with IC die metallization features of a minimum pitch employed in a high bandwidth memory (HBM) application. Although dimensions can vary, in some examples pitch P1 comprises less than 3 μm metallization feature widths and less than 3 μm spaces. As further illustrated, another subset of TGVs may have a second lateral pitch P2 (e.g., along at least the x-axis) that is significantly larger than pitch P1. In some examples pitch P2 comprises more than 3 μm metallization feature widths and more than 3 μm spaces.

In some examples illustrated in FIG. 2, glass substrate 216 may only comprise TGVs 211 having the relaxed lateral pitch P2. The variations illustrated in FIG. 2 may be implemented within different workpieces 200, for example, but are illustrated together for the sake of clarity. TGVs 211 and/or 212 may have any architecture and generally include a metallization, such as, but not limited to, Cu. TGVs 211 and/or 212 may be prefabricated in glass substrate 216 as received or may be fabricated into a starting glass substrate. Regardless, through vias may be formed in glass substrate 216, for example, with a milling, ablation, or etching process. Metallization may be then deposited in the through via openings, for example with a plating process.

FIG. 3A illustrates a cross-sectional view of workpieces 200, in accordance with some further embodiments. As shown in one example, one or more thin film material layers 315 may be on one or both of a first side 214 or a second side 215 of glass substrate 216. Thin film material layer 315 may comprise silicon nitride (SiNₓ) or silicon oxynitride (SiOₓN_{y}), for example. Alternatively, thin film material layer 315 may also be a solder resist with openings that expose TGVs 211 and/or 212.

Workpieces 200 may be processed to form one or more recesses or cavities 314 into glass substrate 216. Substrate cavity 314 is to host one or more IC dies and is dimensioned accordingly. A substrate cavity 314 may be through a portion of substrate thickness T1 or extend all the way through substrate thickness T1. Cavity 314 may be patterned into glass substrate 216 according to any methods known to be suitable, for example in substantially the same manner openings for TGVs 211 and/or 212 are patterned. In some embodiments, cavity 314 is mechanically milled into glass substrate 216. In other embodiments, cavity 314 is formed with a laser, for example through the ablation of the glass or some modification of the glass that renders the glass susceptible to etch. In still other embodiments, cavity 314 is formed with a masked etch process, which may either comprise a dry plasma or wet chemical etch.

FIG. 3B illustrates a plan view of workpieces 200, in accordance with the exemplary embodiments. The sectional view illustrated in FIG. 3A is demarked by a dashed line A-A′ in FIG. 3B. As shown, TGVs 212 are arrayed around an array of TGVs 211, if present. For other embodiments TGVs 212 are array around cavity 314. In these exemplary embodiments, TGVs 212 are within a perimeter portion surrounding an interior portion of glass substrate 216.

Returning to FIG. 1, methods 101 continue with receipt of a first IC die at input 115. The IC die received may be a fully functional ASIC, or may be a chiplet or tile that has more limited functionality supplementing one or more other IC dies that are to be part of the same multi-chip device. A chiplet or tile may, for example, be any of a wireless radio circuit, microprocessor core, electronic memory circuit, floating point gate array (FPGA), power management and/or power supply circuit, or include a MEMS device. In some examples, the IC die received at input 115 includes one or more banks of active repeater circuitry to improve multi-chip interconnects (e.g., network-on-chip architectures). In some examples, the IC die received at input 115 includes clock generator circuitry or temperature sensing circuitry. Advantageously, the IC die received at input 115 includes logic circuitry. In some specific examples, the logic circuitry includes microprocessor core circuitry, for example comprising one or more shift registers. Such microprocessor core circuitry may be part of an intelligence processing unit (IPU), graphical process unit (GPU) or central processing unit, for example.

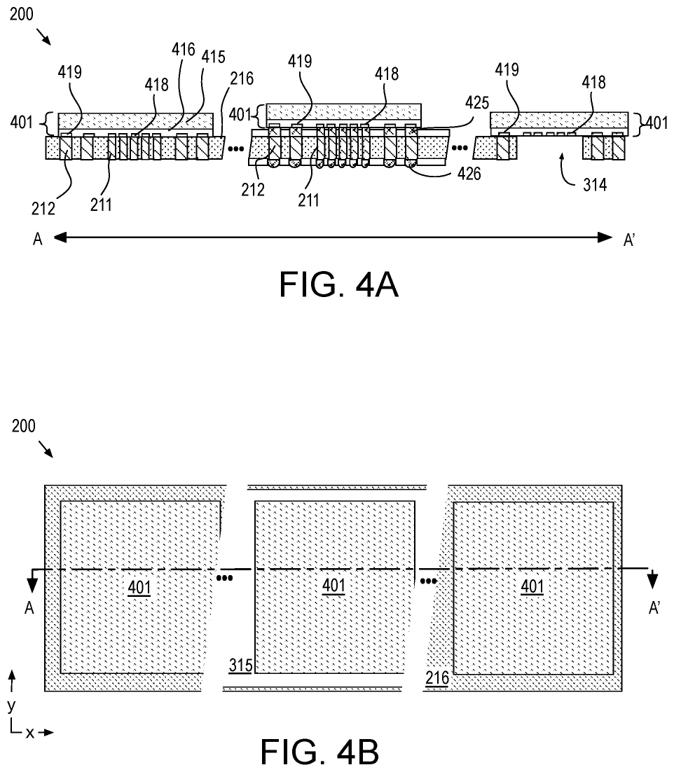

Methods 101 continue at block 120 where the first IC die is attached to a first side of the glass substrate with at least some metallization features of the IC die coupled to the TGVs. The IC die may be positioned upon the first side of the glass substrate and attached either by direct bonding or by a reflow of solder features dispensed upon the IC die or glass substrate. In the examples illustrated in FIGS. 4A and 4B, IC die 401 has IC layers 416 on a die front side and further comprises a die substrate material 415 on a die back side. In some examples, IC die substrate material 415 is monocrystalline silicon. In other examples, die substrate material 415 is an alternative crystalline material, such as, but not limited to, germanium, SiₓGe₁₋ₓ, GeₓSn₁₋ₓ or silicon carbide. IC die 401 may be affixed to glass substrate 216 “front-side down,” as shown, so that IC layers 416 are facing glass substrate 216 in a flip-chip configuration. In alternative embodiments where IC die 401 comprises through die vias (not depicted), IC die 410 may be assembled “front-side up” so that IC layers 416 are instead distal from glass substrate 216.

In some embodiments, the active devices within IC layers 416 are field effect transistors (FETs) with a device pitch of 80 nm, or less. The FETs may be of any architecture (e.g., planar, non-planar, single-gate, multi-gate, stacked nanosheet, etc.). In some embodiments, FET terminals have a feature pitch of 10-30 nm. Additionally, or in the alternative, IC layers 416 may include active devices other than FETs. For example, IC layers 416 may include electronic memory structures, spin valves, or the like.

IC layers 416 comprise one or more IC die metallization levels. In exemplary embodiments, IC layers 416 include die metallization features 419 that couple with TGVs 211. IC layers 416 may further include die metallization features 418, for example having a smaller feature pitch, that couple with TGVs 212. While IC die metallization features 418, 419 may have any composition(s) of sufficient electrical conductivity, in exemplary embodiments, IC die metallization features 418 and/or 419 are predominantly copper (Cu). In other examples, metallization features 418 and/or 419 are predominantly other than Cu, such as, but not limited to predominantly Ru, or predominantly W.

In some embodiments, IC die metallization features 418, 419 are directly bonded to TGVs 211, 212, respectively. Direct bonding may be practiced according to any techniques known for die-to-die or die-to-wafer bonding. In some exemplary embodiments, a hybrid bonding process is practiced to bond IC die 401 to coplanar surfaces of metallization features 418 and 419. In other embodiments, IC die metallization features 419 may be directly bonded to TGVs 212 while IC die metallization features 418 remain unbonded within a portion of IC 401 that spans cavity 314. In other embodiments, intervening solder features 425 couple IC die metallization features 418 and/or 419 to TGVs 211 and/or 212. Solder features 425 may have any suitable solder composition (e.g., SAC or a non-melt solder). As illustrated, solder features 426 may be similarly applied to the opposite side of glass substrate 216. For such embodiments solder features 425 may advantageously have a higher reflow temperature than solder features 426.

Returning to FIG. 1, methods 101 continue with the receipt of a second IC die at input 125. The IC die received may also be a fully functional ASIC, or chiplet or tile with a more limited functionality to supplement the IC die received at input 115. A chiplet or tile may, for example, be any of a wireless radio circuit, microprocessor core, electronic memory circuit, FPGA, power management and/or power supply circuit, or include a MEMS device. In some examples, the IC die received at input 125 includes one or more banks of active repeater circuitry to improve multi-chip interconnects (e.g., network-on-chip architectures). In some examples, the IC die received at input 125 includes clock generator circuitry or temperature sensing circuitry. Advantageously, the IC die received at input 125 includes memory circuitry designed to supplement logic circuitry of the IC die received at input 115. In some specific examples, the memory circuitry includes arrays of memory bit-cells, for example comprising charge storage capacitors (e.g., DRAM, etc.). Such memory circuitry may couple with the IC die received at input 115 and implement a HBM architecture, for example as a component of a multi-chip intelligence processor, multi-chip graphical processor or multi-chip central processor, for example.

Methods 101 continue at block 130 where metallization features of the second IC die are coupled to metallization features of the first IC die. The second IC die is advantageously vertically stacked with the first IC die with or without some portion of the glass substrate between the two stacked IC dies. For some embodiments, the second IC die is attached to some of the TGVs that are further coupled to the first IC die. For such embodiments, metallization features of the second IC may be positioned upon the second side of the glass substrate and attached either by direct bonding to the TGVs or by a reflow of solder features dispensed upon the TGVs or the IC die.

In some embodiments where the second IC die is placed within a cavity in the glass substrate. The IC die within the cavity is laterally adjacent to the TGVs with some portion of the glass substrate between the IC die and the nearest TGV. Within the cavity, the second IC die may be attached to the first IC die either through direct die-to-die metallization feature bonding or through die-to-die metallization solder bonding.

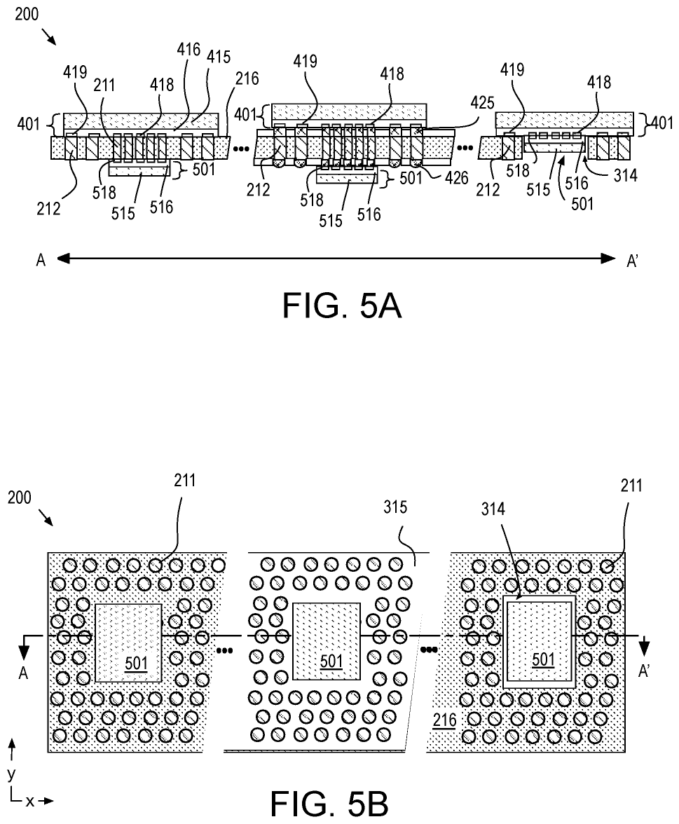

In the examples illustrated in FIGS. 5A and 5B, IC die 501 is attached to workpieces 200. IC die 501 has IC layers 516 on a die front side and further comprises a die substrate material 515 on a die back side. In some examples, IC die substrate material 515 is monocrystalline silicon. In other examples, die substrate material 515 is an alternative crystalline material, such as, but not limited to, germanium, SiₓGe₁₋ₓ, GeₓSn₁₋ₓ or silicon carbide. IC die 501 may be attached in a “face-to-face” or “front-side down” orientation relative to IC die 401 so that IC layers 516 are facing IC layers 416. In alternative embodiments where IC die 501 comprises through die vias (not depicted), IC die 501 may instead be assembled “back-to-face” or “back-to-back” orientation relative to IC die 401.

In some embodiments, the active devices within IC layers 516 are field effect transistors (FETs) with a device pitch of 80 nm, or less. The FETs may be of any architecture (e.g., planar, non-planar, single-gate, multi-gate, stacked nanosheet, etc.). In some embodiments, FET terminals have a feature pitch of 10-30 nm. Additionally, or in the alternative, IC layers 516 may include active devices other than FETs. For example, IC layers 516 may include electronic memory structures (e.g., charge storage capacitors), spin valves, or the like.

IC layers 516 comprise one or more IC die metallization levels. In exemplary embodiments, IC layers 516 include die metallization features 518 that are electrically coupled with die metallization features 418. Metallization features 518 have a layout complementary to that of metallization features 418 with a matching lateral pitch P1. While IC die metallization features 518 may have any composition(s) of sufficient electrical conductivity, in exemplary embodiments, IC die metallization features 518 are predominantly copper (Cu). In other examples, metallization features 518 are predominantly other than Cu, such as, but not limited to predominantly Ru, or predominantly W.

In some embodiments, IC die metallization features 518 are directly bonded to a second end of TGVs 211 having a layout and pitch suitable for direct bonding to metallization features 518 as well as metallization features 418. Direct bonding may be practiced according to any techniques known for die-to-die or die-to-wafer bonding. In some exemplary embodiments, a hybrid bonding process is practiced to bond IC die 501 to a second end of TGVs 211. In other embodiments, metallization features 518 are coupled to a second end of TGVs 211 through intervening solder features 426. Solder features 426 may have any suitable solder composition (e.g., SAC). For embodiments where metallization features 418 are also solder bonded to an opposite end of TGVs 211, solder features 426 may advantageously have a lower solder reflow temperature than solder features 425.

For embodiments where IC die 501 is positioned within cavity 314, metallization features 518 may be directly bonded to metallization features 418 with no intervening TGV or other metallization. Direct bonding may sinter metallization features 418 and 518 (e.g., via metal interdiffusion) and also bond dielectric materials (e.g., via Si—O—Si condensation bonds) at the surface of IC layers 416 and 516. Thermo-compression bonding may be practiced, for example, at low temperature (e.g., below melting temperature of the interconnects, and more specifically below 100° C.). Direct bonding at room temperature (i.e., compression only) may also be suitable. The resulting composite, quasi-monolithic structure may comprise a hybrid bonded interface of both metallurgically interdiffused metals and chemically bonded dielectric materials.

A longer edge length of IC die 401 is sufficient for IC die 401 to overlap IC die 501 and to further contact TGVs 212 positioned within a region of glass substrate 216 that is beyond an edge of IC die 501. IC die 501 therefore overlaps metallization features 418 of minimum pitch P1, but does not overlap metallization features 419 coupled to TGVs 212. As further illustrated FIG. 5B, second ends of TGVs 212 therefore remain available for further electrical interconnection after attachment of IC die 501. In some examples where IC die 501 is significantly smaller in footprint than IC die 401, arrayed TGVs 212 may substantially surround the perimeter edge(s) of IC die 401.

Returning to FIG. 1, methods 101 may continue at block 140 where package dielectric and package routing structure features may be fabricated adjacent to the IC die attached at block 130. Block 140 is shown in dashed line to emphasize the formation of a package-level routing structure is an optional means of electrically routing any TGVs remaining after attachment of IC die 401. The routing structure fabricated at block 140 may be terminated with FLI interconnect features suitable for attachment to a component that is to host the multi-chip device comprising IC dies 401 and 501. In exemplary embodiments, the RDL metallization features formed at block 140 comprise lateral runs fanning out I/O from TGVs and terminating at interconnect interfaces that are to be interconnected with a host of the multi-chip device. The number of layers and/or thicknesses of RDL metallization may vary according to implementation and requirements of the IC dies included within a multi-chip device. If block 140 is not practiced, TGVs remaining available after the attachment of IC die 501 may instead be directly interconnected (e.g., with FLI) to a host component, for example as a means of electrically interfacing the multi-chip device with the host component.

Methods 101 complete at output 150 where the multi-chip device is singulated and attached to the host component. Multi-chip devices may be separated, for example, by kerf or panel frame with each multi-chip device including at least IC dies 401 and 501 that are in a stacked configuration interconnected to each other. Output 150 may be practiced as part of methods 101, or practiced downstream of methods 101 (e.g., at a system-level assembly house).

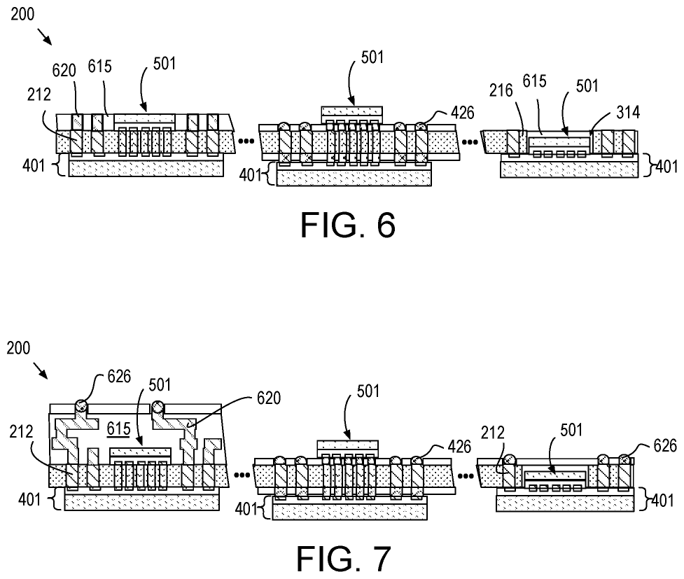

FIG. 6 illustrates a cross-section view of workpieces 200 for examples with and without application of a package dielectric or package routing structure. In examples where TGVs 212 are to be directly interconnected by solder features 426 to a host component, no package dielectric need be applied with solder features 426 laterally adjacent to an edge of IC die 501 remaining exposed.

In other examples, IC die 501 may be encapsulated in a first layer of package dielectric material 615. Package dielectric material 615 may be a dry film laminate, a spin-on build-up material, or a mold material applied around IC die 501, and over exposed portions of glass substrate 216 and TGVs 212. Package dielectric 615 may be cast wet/uncured and then dried/cured. Alternatively, package dielectric 615 may be introduced as a semi-cured dry film that is fully cured following its application to workpieces 200.

In some embodiments, package dielectric material 615 is an organic material, such as, an epoxy resin, phenolic-glass, or a resinous film such as the GX-series films commercially available from Ajinomoto Fine-Techno Co., Inc. (ABF). Package dielectric material 615 may comprise epoxy resins (e.g., an acrylate of novolac such as epoxy phenol novolacs (EPN) or epoxy cresol novolacs (ECN)). In some specific examples, package dielectric 615 is a bisphenol-A epoxy resin, for example including epichlorohydrin. In other examples, package dielectric material 615 includes bisphenol-F epoxy resin (with epichlorohydrin). In other examples, package dielectric material 615 includes aliphatic epoxy resin, which may be monofunctional (e.g., dodecanol glycidyl ether), difunctional (butanediol diglycidyl ether), or have higher functionality (e.g., trimethylolpropane triglycidyl ether). In still other examples, package dielectric material 615 includes glycidylamine epoxy resin, such as triglycidyl-p-aminophenol (functionality 3) and N,N,N′,N′-tetraglycidyl-bis-(4-aminophenyl)-methane (functionality 4).

In some embodiments, package dielectric material 615 planarizes IC die 501 with glass substrate 216 and may fill remnants of cavity 314 between sidewalls of IC die 501 and glass substrate 216. In some embodiments where package dielectric material 615 surrounds an edge of IC die 510, a first level of conductive RDL metallization features 620 may be embedded within the package dielectric material 615. Metallization features 620 may be formed, for example, according to an additive or semi-additive process. The first level of metallization features 620 may be conductive vias, for example, that extend through the first layer of package dielectric material 615 (e.g., that is at least as thick as IC die 501) and contact TGVs 212 to convey signal I/O to/from at least IC die 401. In the exemplary embodiments, the height of metallization features 620 is at least equal to the total thickness of IC die 501, which is indicative of metallization features 620 having been formed after the attachment of IC die 501.

Any technique suitable for the composition of package dielectric material 615 may be employed to form metallization features 620. For embodiments where package dielectric material 615 is photosensitive, a lithographic process may directly pattern package dielectric material 615. Alternatively, a photolithographic masking process may be performed and package dielectric material 615 etched according to the mask. In other embodiments, openings package dielectric material 615 may be ablated, for example with a laser. Metallization features 620 may be formed by first depositing a seed layer (e.g., Cu) and then forming a plating resist mask (not depicted) over the seed layer. With an electrolytic deposition process, Cu is plated upon the seed layer wherever the resist mask is absent.

FIG. 7 further illustrates a cross-sectional view of workpieces 200 terminated with FLI features 626 or 426 for embodiments with and without package routing structure, respectively. Any number of layers of package dielectric material 615 may be optionally built up to complete a multi-chip device. Within each additional dielectric material layer, another level of RDL metallization features 620 may be formed to complete a routing structure coupled to TGVs 212 laterally adjacent to a sidewall of IC die 501. Metallization features 620 terminated at FLI features 626. In other embodiments where no metallization features 620 are built-up, FLI features 626 may be formed directly upon TGVs 212.

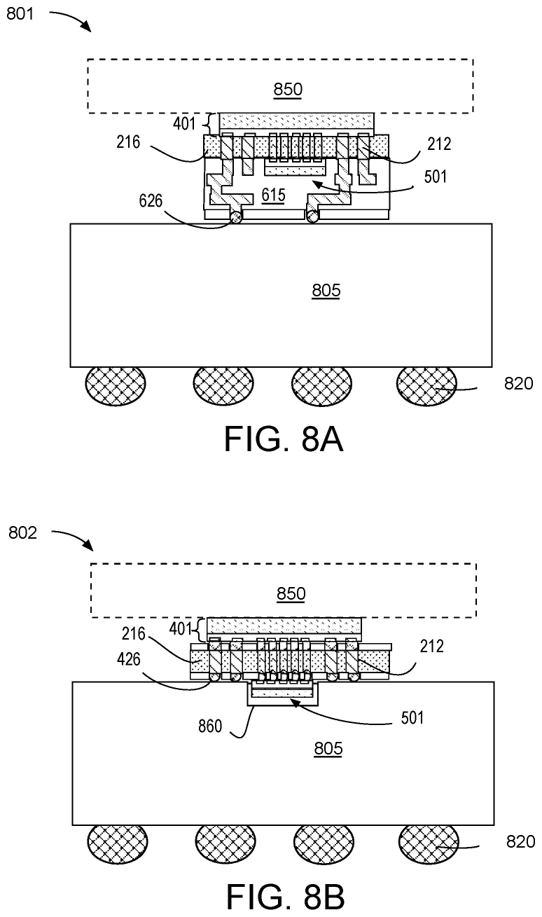

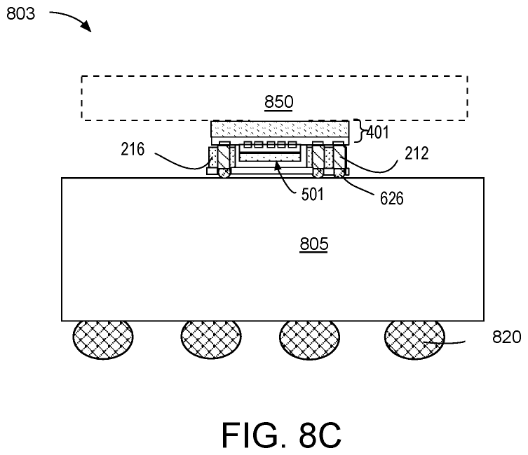

FIGS. 8A-8C illustrate systems including exemplary multi-chip devices assembled to a host component 805 with FLI features 426 or 626, in accordance with some embodiments. As shown in FIG. 8A, system 801 includes a multi-chip device including stacked IC die 401 and 501 with an intervening glass substrate 216. In exemplary embodiments, FLI interconnects 626 are solder (e.g., SAC) microbumps although other interconnect features are also possible. Host component 805 may also comprise one or more materials known to be suitable as interposers or package substrates (e.g., an epoxy preform, cored or coreless laminate board, etc.). Host component 805 may include one or more metallized redistribution levels (not depicted) embedded within a dielectric material. Host component 805 may also include one or more IC die embedded therein.

Host component 805 may further include second level interconnects (SLI) 820. SLI 820 may comprise any solder (ball, bump, etc.) suitable for a given host board architecture (e.g., surface mount FR4, etc.). As illustrated in dashed line, one or more heat spreaders and/or heat sinks 850 may be further coupled to IC die 401, which may be advantageous, for example, where IC 401 comprises logic circuitry, such as one or more CPU cores or other architectures of similar power density.

In FIG. 8B, system 802 includes many of the same features of system 801 but with solder features 426 adjacent to IC die 501 serving as FLI interconnect to host component 805. As noted above, solder features 426 may advantageously have a lower solder reflow temperature than at least solder features 425. Solder features 426 reflowed during attachment to host component 805 may also have a different (e.g., lower) reflow temperature than any solder features employed to bond IC die 501 to glass substrate 216. In absence of package dielectric adjacent to IC die 501, host component 805 comprises a recess 860 to accommodate the projection of IC die 501 beyond a plane of solder features 426. In FIG. 8C, a system 803 includes many of the same features of systems 801 and 802. However, in system 803 solder features 626 are the only intervening metallization between TGVs 212 and host component 805.

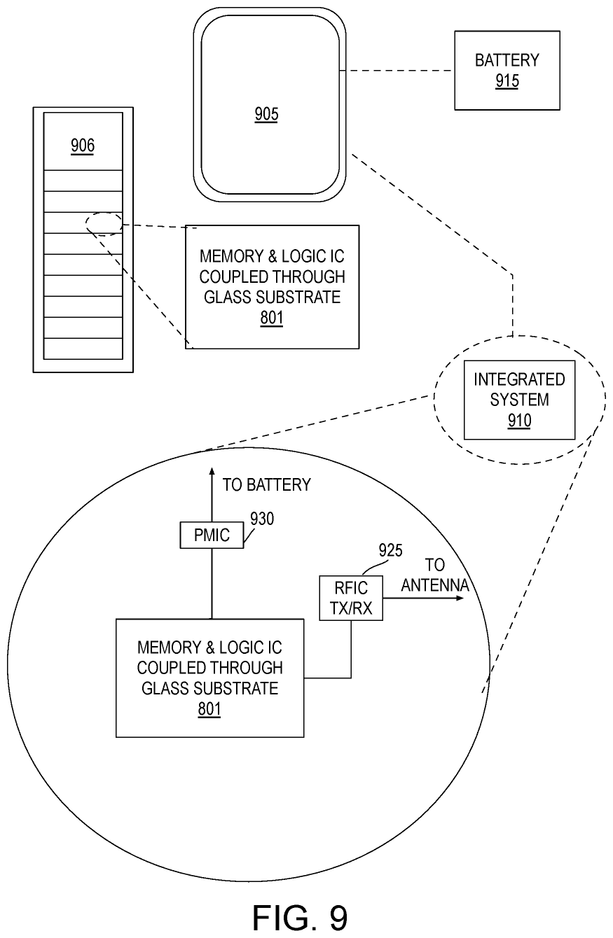

FIG. 9 illustrates a mobile computing platform 905 and a data server machine 906 employing a multi-chip IC device with memory and logic IC dies coupled through a glass substrate, for example as described elsewhere herein. Server machine 906 may be any commercial server, for example including any number of high-performance computing platforms disposed within a rack and networked together for electronic data processing, which in the exemplary embodiment includes multichip device 801, for example as described elsewhere herein. The mobile computing platform 905 may be any portable device configured for each of electronic data display, electronic data processing, wireless electronic data transmission, or the like. For example, the mobile computing platform 905 may be any of a tablet, a smart phone, laptop computer, etc., and may include a display screen (e.g., a capacitive, inductive, resistive, or optical touchscreen), an integrated system 910, and a battery 915.

As illustrated in the expanded view, multi-chip device 801 is coupled to one or more of a power management integrated circuit (PMIC) 930 or RF (wireless) integrated circuit (RFIC) 925 including a wideband RF (wireless) transmitter and/or receiver. A PMIC may perform battery power regulation, DC-to-DC conversion, etc., and so has an input coupled to battery 915 and with an output providing a current supply to other functional modules. As further illustrated, in the exemplary embodiment, an RFIC has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, and beyond.

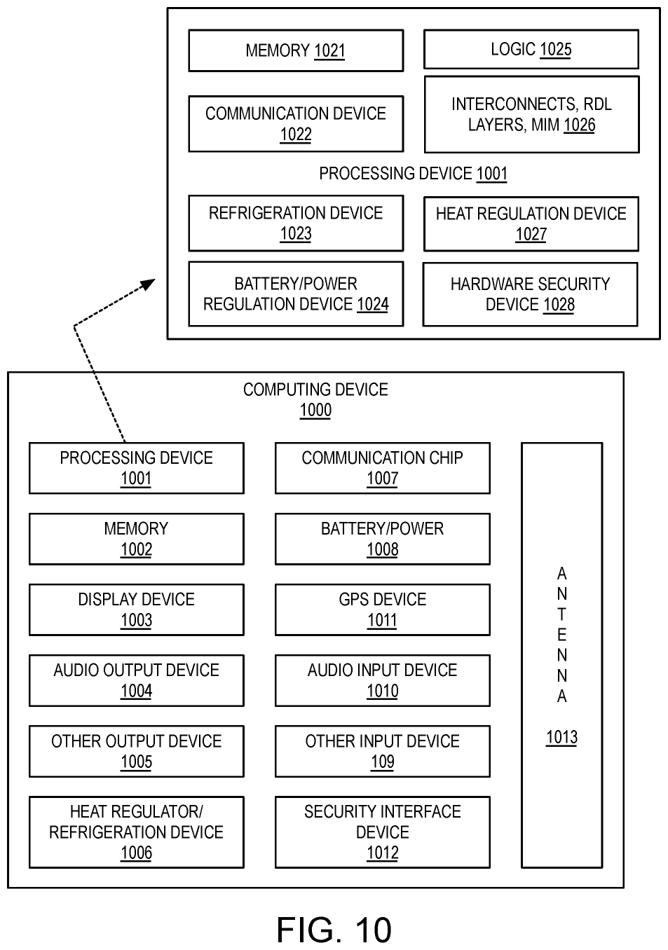

FIG. 10 is a block diagram of a cryogenically cooled computing device 1000 in accordance with some embodiments. For example, one or more components of computing device 1000 may include any of the devices or structures discussed elsewhere herein. A number of components are illustrated in FIG. 10 as included in computing device 1000, but any one or more of these components may be omitted or duplicated, as suitable for the application. In some embodiments, some or all of the components included in computing device 1000 may be attached to one or more printed circuit boards (e.g., a motherboard). In some embodiments, various ones of these components may be fabricated onto a single system-on-a-chip (SoC) die. Additionally, in various embodiments, computing device 1000 may not include one or more of the components illustrated in FIG. 10, but computing device 1000 may include interface circuitry for coupling to the one or more components. For example, computing device 1000 may not include a display device 1003, but may include display device interface circuitry (e.g., a connector and driver circuitry) to which display device 1003 may be coupled.

Computing device 1000 may include a processing device 1001 (e.g., one or more processing devices). As used herein, the term processing device or processor indicates a device that processes electronic data from registers and/or memory to transform that electronic data into other electronic data that may be stored in registers and/or memory. Processing device 1001 may include a memory 1021, a communication device 1022, a refrigeration/active cooling device 1023, a battery/power regulation device 1024, logic 1025, interconnects 1026, a heat regulation device 1027, and a hardware security device 1028.

Processing device 1001 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

Processing device 1001 may include a memory 1002, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1021 includes memory that shares a die with processing device 1002. This memory may be used as cache memory and may include embedded dynamic random-access memory (eDRAM) or spin transfer torque magnetic random-access memory (STT-M RAM).

Computing device 1000 may include a heat regulation/refrigeration device 1006. Heat regulation/refrigeration device 1006 may maintain processing device 1002 (and/or other components of computing device 1000) at a predetermined low temperature during operation. This predetermined low temperature may be any temperature discussed elsewhere herein.

In some embodiments, computing device 1000 may include a communication chip 1007 (e.g., one or more communication chips). For example, the communication chip 1007 may be configured for managing wireless communications for the transfer of data to and from computing device 1000. The term “wireless” and its derivatives may be used to describe circuits, devices, systems, methods, techniques, communications channels, etc., that may communicate data through the use of modulated electromagnetic radiation through a nonsolid medium.

Communication chip 1007 may implement any wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1007 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1007 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1007 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1007 may operate in accordance with other wireless protocols in other embodiments. Computing device 1000 may include an antenna 1013 to facilitate wireless communications and/or to receive other wireless communications (such as AM or FM radio transmissions).

In some embodiments, communication chip 1007 may manage wired communications, such as electrical, optical, or any other suitable communication protocols (e.g., the Ethernet). As noted above, communication chip 1007 may include multiple communication chips. For instance, a first communication chip 1007 may be dedicated to shorter-range wireless communications such as Wi-Fi or Bluetooth, and a second communication chip 1007 may be dedicated to longer-range wireless communications such as GPS, EDGE, GPRS, CDMA, WiMAX, LTE, EV-DO, or others. In some embodiments, a first communication chip 1007 may be dedicated to wireless communications, and a second communication chip 1007 may be dedicated to wired communications.

Computing device 1000 may include battery/power circuitry 1008. Battery/power circuitry 1008 may include one or more energy storage devices (e.g., batteries or capacitors) and/or circuitry for coupling components of computing device 1000 to an energy source separate from computing device 1000 (e.g., AC line power).

Computing device 1000 may include a display device 1003 (or corresponding interface circuitry, as discussed above). Display device 1003 may include any visual indicators, such as a heads-up display, a computer monitor, a projector, a touchscreen display, a liquid crystal display (LCD), a light-emitting diode display, or a flat panel display, for example.

Computing device 1000 may include an audio output device 1004 (or corresponding interface circuitry, as discussed above). Audio output device 1004 may include any device that generates an audible indicator, such as speakers, headsets, or earbuds, for example.

Computing device 1000 may include an audio input device 1010 (or corresponding interface circuitry, as discussed above). Audio input device 1010 may include any device that generates a signal representative of a sound, such as microphones, microphone arrays, or digital instruments (e.g., instruments having a musical instrument digital interface (MIDI) output).

Computing device 1000 may include a global positioning system (GPS) device 1009 (or corresponding interface circuitry, as discussed above). GPS device 1009 may be in communication with a satellite-based system and may receive a location of computing device 1000, as known in the art.

Computing device 1000 may include another output device 1005 (or corresponding interface circuitry, as discussed above). Examples include an audio codec, a video codec, a printer, a wired or wireless transmitter for providing information to other devices, or an additional storage device.

Computing device 1000 may include another input device 1011 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1000 may include a security interface device 1012. Security interface device 1012 may include any device that provides security measures for computing device 1000 such as intrusion detection, biometric validation, security encode or decode, managing access lists, malware detection, or spyware detection.

Computing device 1000, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that this disclosure not limited to the embodiments so described but can be practiced with modification and alteration without departing from the scope of the appended claims. For example, the above embodiments may include specific combinations of features as further provided below.

In first examples an apparatus comprises a glass substrate and a plurality of through vias extending through a thickness of the glass substrate. The apparatus comprises a logic IC die on a first side of the glass substrate and comprising first metallization features facing the glass substrate. First ones of the first metallization features are coupled to first ones of the through vias. The apparatus comprises a memory IC die in a stack with the logic IC die, the memory IC die comprising second metallization features facing, and coupled to, second ones of the first metallization features.

In second examples, for any of the first examples the thickness of the glass substrate is between the logic IC die and the memory IC die and the second ones of the first metallization features are coupled to a first end of second ones of the through vias.

In third examples, for any of the first through second examples the first ones of the first metallization features are directly bonded to the first ones of the through vias, and the second ones of the first metallization features are directly bonded to the second ones of the through vias.

In fourth examples, for any of the third examples the second metallization features are directly bonded to a second end of the second ones of the through vias.

In fifth examples, for any of the third examples the second metallization features are coupled through solder features to a second end of the second ones of the through vias.

In sixth examples, for any of the fifth examples the solder features are first solder features, and the IC device further comprises second solder features laterally adjacent to the memory IC die and coupled to a second end of the first ones of the through vias, the second solder features having a lower reflow temperature than the first solder features.

In seventh examples, for any of the first through sixth examples solder features couple the first and second ones of the first metallization features to the first and second ones of the through vias, the second solder features having a lower reflow temperature than the first solder features.

In eighth examples, for any of the seventh examples the solder features are first solder features, and the second metallization features are coupled through second solder features to the second end of the second ones of the through vias.

In ninth examples, for any of the eighth examples the IC device further comprises package-level solder interconnect features laterally adjacent to the memory IC die and coupled to the second end of the first ones of the through vias. The package-level solder interconnect features have a lower reflow temperature than the first solder features.

In tenth examples, for any of the first through ninth examples the IC device further comprises package-level solder interconnect features laterally adjacent to the memory IC die and coupled to a second end of the first ones of the through vias.

In eleventh examples, for any of the first through ninth examples the IC device further comprises a package dielectric material laterally adjacent to the memory IC die, and a routing structure within the package dielectric material. The routing structure comprises via metallization features in direct contact with a second end of the first ones of the through vias. The routing structure terminates at first-level interconnect interfaces.

In twelfth examples, for any of the first examples at least one of the logic IC die or memory IC die is embedded within the glass substrate and at least a portion of a sidewall of the logic IC die or memory IC die is laterally adjacent to the through vias with a portion of the glass substrate therebetween.

In thirteenth examples, for any of the twelfth examples the first ones of the first metallization features are directly bonded to the first ones of the through vias, and the second ones of the first metallization features are directly bonded to the second metallization features.

In fourteenth examples, a system comprises a multi-chip integrated circuit (IC) device comprising a glass substrate, a plurality of through vias extending through a thickness of the glass substrate, and a logic IC die on a first side of the glass substrate and comprising first metallization features facing the glass substrate. First ones of the first metallization features are coupled to first ones of the through vias. The multi-chip IC device comprises a memory IC die in a stack with the logic IC die. The memory IC die comprises second metallization features facing, and coupled to, second ones of the first metallization features through second ones of the through vias. The multi-chip IC device comprises a package dielectric material adjacent to a sidewall of the memory IC die and a routing structure embedded within the package dielectric material. The routing structure comprises metallization features in contact with the first ones of the through vias and terminating at first-level interconnect interfaces. The system comprises a host component interconnected to the routing structure through first-level interconnects coupled to the first-level interconnect interfaces.

In fifteenth examples, for any of the fourteenth examples the first-level interconnect features comprise solder.

In sixteenth examples for any of the fourteenth through fifteenth examples the system further comprises a power supply coupled through the host component to provide power to at least the logic IC die through the first ones of the through vias.

In seventeenth examples a method of forming an integrated circuit (IC) device comprises receiving a glass substrate comprising a plurality of electrically conductive through vias, coupling a logic IC die to a first side of the glass substrate with first metallization features coupled to first ones of the through vias, and coupling a memory IC die with second metallization features to second ones of the first metallization features. The first ones of the through vias are beyond an edge of the memory IC die.

In eighteenth examples, for any of the seventeenth examples the method further comprises coupling a second end of the first ones of the through vias to a host component.

In nineteenth examples, for any of the eighteenth examples coupling the second end of the first ones of the through vias to the host component comprises forming solder features upon the second end of the first ones of the through vias.

In twentieth examples, for any of the nineteenth examples coupling the second end of the first ones of the through vias to the host component comprises building up metallization features within a package dielectric material adjacent to a sidewall of the memory IC die and in contact with the first ones of the through vias.

However, the above embodiments are not limited in this regard, and, in various implementations, the above embodiments may include the undertaking of only a subset of such features, undertaking a different order of such features, undertaking a different combination of such features, and/or undertaking additional features than those features explicitly listed. The scope of the claims should therefore include full scope of equivalents to which such claims are entitled.

What is claimed is:

1. An apparatus comprising:
a glass substrate;
a plurality of through vias extending through a thickness of the glass substrate;
a logic IC die on a first side of the glass substrate and comprising first metallization features facing the glass substrate, wherein first ones of the first metallization features are coupled to first ones of the through vias; and
a memory IC die in a stack with the logic IC die, the memory IC die comprising second metallization features facing, and coupled to, second ones of the first metallization features.

2. The apparatus of claim 1, wherein:
the thickness of the glass substrate is between the logic IC die and the memory IC die; and
the second ones of the first metallization features are coupled to a first end of second ones of the through vias.

3. The apparatus of 1, wherein the first ones of the first metallization features are directly bonded to the first ones of the through vias, and the second ones of the first metallization features are directly bonded to the second ones of the through vias.

4. The apparatus of claim 3, wherein the second metallization features are directly bonded to a second end of the second ones of the through vias.

5. The IC device of claim 3, wherein the second metallization features are coupled through solder features to a second end of the second ones of the through vias.

6. The apparatus of claim 5, wherein:
the solder features are first solder features; and
the IC device further comprises second solder features laterally adjacent to the memory IC die and coupled to a second end of the first ones of the through vias, the second solder features having a lower reflow temperature than the first solder features.

7. The apparatus of claim 1, wherein solder features couple the first and second ones of the first metallization features to the first and second ones of the through vias, the second solder features having a lower reflow temperature than the first solder features.

8. The apparatus of claim 7, wherein:
the solder features are first solder features; and
the second metallization features are coupled through second solder features to the second end of the second ones of the through vias.

9. The apparatus of claim 8, wherein the IC device further comprises package-level solder interconnect features laterally adjacent to the memory IC die and coupled to the second end of the first ones of the through vias, the package-level solder interconnect features having a lower reflow temperature than the first solder features.

10. The apparatus of claim 1, wherein the IC device further comprises package-level solder interconnect features laterally adjacent to the memory IC die and coupled to a second end of the first ones of the through vias.

11. The apparatus of claim 1, wherein the IC device further comprises:
a package dielectric material laterally adjacent to the memory IC die; and
a routing structure within the package dielectric material, the routing structure comprising via metallization features in direct contact with a second end of the first ones of the through vias, the routing structure terminating at first-level interconnect interfaces.

12. The apparatus of claim 1, wherein at least one of the logic IC die or memory IC die is embedded within the glass substrate and at least a portion of a sidewall of the logic IC die or memory IC die is laterally adjacent to the through vias with a portion of the glass substrate therebetween.

13. The apparatus of claim 12, wherein the first ones of the first metallization features are directly bonded to the first ones of the through vias, and the second ones of the first metallization features are directly bonded to the second metallization features.

14. A system comprising:
a multi-chip integrated circuit (IC) device comprising:
a glass substrate;
a plurality of through vias extending through a thickness of the glass substrate;
a logic IC die on a first side of the glass substrate and comprising first metallization features facing the glass substrate, wherein first ones of the first metallization features are coupled to first ones of the through vias; and
a memory IC die in a stack with the logic IC die, the memory IC die comprising second metallization features facing, and coupled to, second ones of the first metallization features through second ones of the through vias;
a package dielectric material adjacent to a sidewall of the memory IC die;
a routing structure embedded within the package dielectric material, the routing structure comprising metallization features in contact with the first ones of the through vias and terminating at first-level interconnect interfaces; and
a host component interconnected to the routing structure through first-level interconnects coupled to the first-level interconnect interfaces.

15. The system of claim 14, wherein the first-level interconnect features comprise solder.

16. The system of claim 14, further comprising a power supply coupled through the host component to provide power to at least the logic IC die through the first ones of the through vias.

17. A method of forming an integrated circuit (IC) device, the method comprising:
receiving a glass substrate comprising a plurality of electrically conductive through vias;
coupling a logic IC die to a first side of the glass substrate with first metallization features coupled to first ones of the through vias; and
coupling a memory IC die with second metallization features coupled to second ones of the first metallization features, wherein the first ones of the through vias are beyond an edge of the memory IC die.

18. The method of claim 17 further comprising coupling a second end of the first ones of the through vias to a host component.

19. The method of claim 18, wherein coupling the second end of the first ones of the through vias to the host component comprises forming solder features upon the second end of the first ones of the through vias.

20. The method of claim 18, wherein coupling the second end of the first ones of the through vias to the host component comprises building up metallization features within a package dielectric material adjacent to a sidewall of the memory IC die and in contact with the first ones of the through vias.
